(19) United States
(12) Patent Application Publication
(10) Pub. No.: US 2025/0228021 A1
(43) Pub. Date: Jul. 10, 2025

(54) A COMBINED SHORT-WAVELENGTH INFRARED AND VISIBLE LIGHT SENSOR

(71) Applicant: SEMICONDUCTOR COMPONENTS INDUSTRIES, LLC, Scottsdale, AZ (US)

(72) Inventors: Ross F. JATOU, San Jose, CA (US); Vladimir KOROBOV, San Mateo, CA (US); Swarnal BORTHAKUR, Boise, ID (US)

(73) Assignee: SEMICONDUCTOR COMPONENTS INDUSTRIES, LLC, Scottsdale, AZ (US)

(21) Appl. No.: 18/854,008

(22) PCT Filed: Oct. 10, 2023
(86) PCT No.: PCT/US2023/076407

§ 371 Date: Oct. 3, 2024

Related U.S. Application Data
(60) Provisional application No. 63/414,182, filed on Oct. 7, 2022.

(51) Int. Cl. H10F 39/18; B82Y 20/00; H10F 39/00

(52) U.S. Cl. CPC H10F 39/1843; B82Y 20/00; H10F 39/014; H10F 39/018; H10F 39/024; H10F 39/182; H10F 39/8037; H10F 39/8053; H10F 39/8063; H10F 39/807; H10F 39/809; H10F 39/811

(57) ABSTRACT

A sensor includes an array of optically active pixels disposed on a semiconductor die. The array of optically active pixels includes at least one pixel (P1) configured to detect short wavelength infrared radiation (SWIR), and at least one pixel (P2) configured to detect visible light incident on the sensor.

### RELATED APPLICATIONS

This application claims priority to, and the benefit of, U.S. Provisional Patent application No. 63/414,182, filed Oct. 7, 2022, which is incorporated by reference in its entirety herein.

This application is also related to International Patent Application No. PCT/US23/75098, filed Sep. 26, 2023, claiming priority to, and the benefit of, U.S. Provisional Application No. 63/377,120, filed Sep. 26, 2022, which is incorporated by reference in its entirety herein.

### TECHNICAL FIELD

This description relates to packaging of semiconductor optical sensors.

### BACKGROUND

An optical sensor is configured to convert a radiation intensity and a wavelength spectrum into electrical signals. The optical sensor can include devices for detecting light intensity. An optical sensor fabricated on a semiconductor die includes an optically active surface area (OASA) with an array of pixels responsible for converting a light and color spectrum into electrical signals. The OASA of an optical sensor may also include, for example, a microlens array to help funnel incoming light into each pixel (thereby increasing the sensitivity of the image sensor) and or include a color filter array (CFA).

### SUMMARY

In a general aspect, a sensor includes an array of optically active pixels disposed on a semiconductor die. The array of optically active pixels includes at least one pixel configured to detect short wavelength infrared radiation (SWIR), and at least one pixel configured to detect visible light incident on the sensor.

In a general aspect, an imager includes an optical sensor die including a semiconductor substrate. At least one device is fabricated in the semiconductor substrate. An array of optically active pixels is disposed on the optical sensor die. The array of optically active pixels includes at least one pixel configured to detect short wavelength infrared radiation (SWIR) and at least one pixel configured to detect visible light incident on the optical sensor die.

In a further aspect, an intermetal dielectric (IMD) layer is disposed on a bottom surface of the semiconductor substrate. The IMD layer includes at least a metal level of a redistribution layer of the optical sensor die.

In a general aspect, a method includes forming an optical sensor die including a semiconductor substrate, at least one device being fabricated in the semiconductor substrate, and disposing an array of optically active pixels on the optical sensor die. The method further includes configuring at least one pixel of the array of optically active pixels to detect short wavelength infrared radiation (SWIR) incident on the optical sensor die, and configuring at least one other pixel of the array of optically active pixels to detect visible light incident on the optical sensor die.

The details of one or more implementations are set forth in the accompanying drawings and the description below. Other features will be apparent from the description and drawings, and from the claims.

### BRIEF DESCRIPTION OF THE DRAWINGS

FIGS. 1A, 1B, and 1C illustrate example color filter arrays including mosaics of various color filter elements and infrared filter elements.

FIG. 2 illustrates a cross-sectional view of a combined short wavelength infrared radiation (SWIR) and visible light optical sensor assembly configured for front side illumination.

FIG. 3 is an exploded view of the optical sensor assembly of FIG. 2 illustrating the electrical connections to pixel devices fabricated in the silicon substrate.

FIG. 4A illustrates a cross-sectional view of a portion of the optical sensor assembly of FIG. 2 showing a bottom electrode in a SWIR filter element connected to a metal level of a redistribution layer.

FIG. 4B illustrates a cross-sectional view of a portion of the optical sensor assembly of FIG. 2 showing a bottom electrode in a SWIR filter element connected to a polysilicon gate of a transistor.

FIG. 4C illustrates a cross-sectional view of a portion of the optical sensor assembly of FIG. 2 showing a bottom electrode in a SWIR filter element connected to a source or drain of a transistor.

FIG. 5 illustrates a cross-sectional view of a combined SWIR-Visible light optical sensor assembly configured for backside illumination.

FIG. 6A illustrates a cross-sectional view of a portion of the optical sensor assembly of FIG. 5 showing a bottom electrode in a SWIR filter element connected to a metal level of a redistribution layer.

FIG. 6B illustrates a cross-sectional view of a portion of the optical sensor assembly of FIG. 5 showing a bottom electrode in a SWIR filter element connected to a polysilicon gate of a transistor.

FIG. 6C illustrates a cross-sectional view of a portion of the optical sensor assembly of FIG. 5 showing a bottom electrode in a SWIR filter element connected to a source of a transistor.

FIG. 7 illustrates a cross-sectional view of an example combined SWIR-Visible light optical sensor assembly that includes an infrared sensitivity enhancement feature.

FIG. 8 illustrates a cross-sectional view of a combined SWIR-Visible light optical sensor assembly in which IR filter elements are disposed at centers of a two-by-two array of color filter elements.

FIG. 9 illustrates an example method for fabricating an optical sensor assembly.

FIGS. 10A through 10C illustrate a construction of a mosaic of color filter elements and SWIR filter elements.

In the drawings, which are not necessarily drawn to scale, like reference symbols or alpha numerals may indicate like and/or similar components in different views. The drawings illustrate generally, by way of example, but not by way of limitation, various implementations discussed in the present disclosure. Reference symbols shown in one drawing may not be repeated for the same, and/or similar elements in related views. Reference symbols or alpha-numeral identifiers that are repeated in multiple drawings may not be specifically discussed with respect to each of those drawings but are provided for context between related views. Also, not all like elements in the drawings are specifically referenced with a reference symbol or alpha-numeral identifier when multiple instances of an element are illustrated.

### DETAILED DESCRIPTION

An optical sensor fabricated on a semiconductor die includes an optically active surface area (OASA) including an x-y array of pixel sensors responsible for converting a light and color spectrum into electrical signals. In some implementations, the optical sensor can be a complementary metal-oxide semiconductor (CMOS) pixel sensor. In some implementations, each pixel sensor in the array of pixel sensors may, for example, include a photo diode or a photo transistor that senses and converts incident light into an electrical signal. The OASA of an optical sensor may also include a color filter array (CFA). A CFA may be a mosaic of tiny color filters coupled to the pixel sensors to capture color information. For example, a Bayer RBG color filter or mosaic may include a pattern of red (R), blue (B) and green (G) color filters to capture color information related to the R, B and G colors. The OASA of an optical sensor may also include a microlens array to help funnel incoming light into each pixel to increase the sensitivity of the optical sensor. In some implementations, the microlens array can be an x-y array of microlenses.

A pixel can refer to either an individual pixel sensor device, to the individual pixel sensor and an associated color filter, or collectively to the individual pixel sensor, the associated color filter, and an associated microlens. The individual pixel sensor device can be a photo diode or a photo transistor.

A short-wavelength infrared (SWIR) imager or sensor assembly is a type of optical sensor configured for capturing images in light at wavelengths outside the visible range. An example SWIR imager may, for example, detect and capture images in the short-wavelength infrared (SWIR) region of the electromagnetic spectrum, which ranges from about 900 nm to 2500 nm. In some implementations, the image may be captured at a wavelength of 1550 nm. In some implementations, a SWIR imager may be colloidal quantum dot (CQD) sensor based on a semiconductor material such as silicon material. When a bulk semiconductor material absorbs light, the bulk semiconductor material releases an electron from a chemical bond, and that electron is free to roam through the semiconductor material. The same process happens in a quantum dot structure in which the quantum dots may be only a few nanometers in diameter. However, unlike in bulk semiconductor material, the released electron cannot roam freely. The released electron is quantum confined by the edges of the quantum dot, which is of a limited finite size. The quantum dot may be, for example, only a few nanometers in diameter. A useful property of a quantum dot for imaging is that the light absorbed by the quantum dot is tunable. In some implementations, the quantum dot is tunable so that the color can be continuously adjusted to almost any wavelength in the visible and infrared spectrum simply by choosing the right material, the right dot size, and the right bias voltages. In some implementations, the CQD structures described herein may be configured to detect radiation in the SWIR region of the electromagnetic spectrum.

Newer industrial and consumer applications, for example, automotive applications such as advanced driver assistance systems (ADAS) and autonomous driving (AD) systems, can include other circuitry in the same IC package as the optical sensor die for improved imaging performance. The other circuitry may include an image signal processor (ISP) or an application specific integrated circuit (ASIC). The ISP or the ASIC die, can be coupled to, or combined with the optical sensor die in a package.

The devices of an optical sensor may be fabricated in a semiconductor die (optical sensor die), for example, by wafer-level processing steps, and coupled to circuitry such as an ASIC. The ASIC can include, for example, a driver circuit and an A/D converter. The ASIC circuits may be fabricated on a same semiconductor die as the devices for detecting light intensity, or on a separate ASIC die coupled to the optical sensor die.

In some implementations, an optical sensor and the associated ASIC circuits can produce an electrical output. The raw image (RAW) data generated by the optical sensor may, for example, be in the form of zeroes and ones for each pixel of the optical sensor array. Further, an ISP can be a dedicated processor that converts the RAW data generated by the optical sensor into a workable image output through various signal conditioning processes. These various signal conditioning processes may, for example, include one or more of: noise reduction, lens shading correction, gamma correction, auto exposure, and/or auto white balance.

This disclosure describes an imager (sensor assembly) in which visible light detector pixels, infrared detector pixels and SWIR detector pixels can be fabricated in a single optical sensor die.

The visible light detectors and infrared detectors may, for example, be photodiodes, and the SWIR detectors may be capacitive detectors using a CQD layer as a capacitive material. A color filter array deployed on the pixels in the optical sensor die may include a square or rectangular or hexagonal or any other shape mosaic of various color filter elements.

In some implementations, the square or rectangular mosaic may include filter elements corresponding to the visible color pixels, for example, red, green, and blue, and at least one additional filter element that corresponds to a SWIR detector pixel. The filter element that corresponds to the SWIR detector pixel may be a layer of colloidal quantum dots material disposed between two electrodes forming a SWIR detector capacitor. Because of the longer wavelength of SWIR than the wavelengths of visible radiation, the addition of the SWIR pixel to the color pixels can contribute toward a better resolution of the image output by the ISP that converts the RAW data generated by the optical sensor into a workable image output.

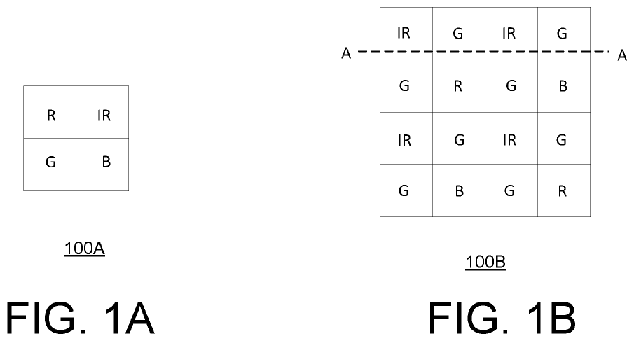

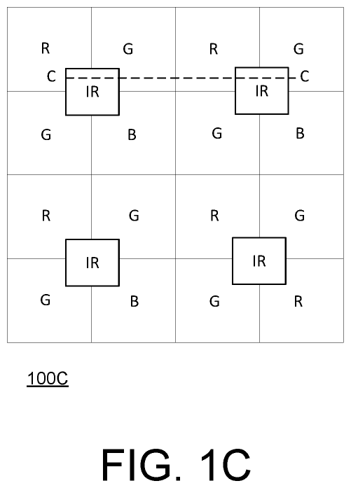

FIG. 1A shows, for example, a 2-by-2 color filter array 100A including a filter element corresponding to a SWIR pixel, according to at least one implementation. Color filter array 100A may have an RGB-IR 2×2 format that includes a total of four pixel elements including an IR filter element corresponding to a SWIR detector pixel, and a blue filter element, a red filter element, and a green filter element corresponding to corresponding three visible light detector pixels.

FIG. 1B shows, for example, a 4-by-4 color filter array 100B including four filter elements corresponding to SWIR pixels, according to at least one implementation. Color filter array 100B may have an RGB-IR 4×4 format that includes two red filter elements, two blue filter elements, eight green filter elements, and four IR filter elements corresponding to SWIR detector pixels.

In some implementations, a filter element corresponding to SWIR detector pixel in a filter array may be a fraction of a pixel in size. FIG. 1C shows, for example, a 2-by-2 color filter array 100C including an IR filter element that is less than one pixel in size. Color filter array 100C may have an RGB-IR 2×2 format that includes a total of four pixel elements including a blue filter element, a red filter element, two green filter element, and an IR filter element that is less than one pixel in size. The IR filter element may be placed at within the 2-by-2 RGGB blocks. In some implementations, the IR filter element may be placed at a center of the 2-by-2 RGGB blocks.

The foregoing example color filter arrays are based on an RGB color scheme for the color pixels. In some other implementations, other color schemes can be used. Any of the various color schemes used, for example, in a variety of cameras or imagers can be used. For example, a color scheme for the color filter arrays may be based on red, green, blue, white colors. For example, another color scheme for the color filter arrays may be based on cyan, yellow, and magenta.

In example implementations, the optical sensor die, in which both visible light detector pixels and SWIR detector pixels are fabricated, may be stacked on an ASIC die, bonded, and/or electrically connected to an ASIC die. In example implementations, the optical sensor die may be directly stacked on an ASIC die, bonded, and/or electrically connected to an ASIC die.

In some example implementations, the optical sensor die may be placed face-to-face with the ASIC die and bonded directly to the ASIC die. In example implementations, fabrication of the optical sensor die, the ASIC die, and the bonding of the two, may involve wafer-level processing steps. The bonded surfaces of the optical sensor die, and the ASIC die may include surface regions of heterogenous materials. The heterogenous materials may, for example, include conductive material such as copper, passivation material such as oxides or other dielectrics, and semiconductor material such as silicon. Bonding of the optical sensor die to the ASIC die may involve techniques such as hybrid bonding for stacking and electrically connecting the dies together. The hybrid bonding may, for example, involve introducing cooper pads disposed, for example, in dielectric material layers on the surfaces of the two dies. The hybrid bonding may further involve stacking the two dies face-to-face, and aligning and fusing the copper pads disposed on opposing surfaces of dies together while bonding the remainder of the opposing surfaces together. As a result, the two dies in the assembly may be electrically connected using small copper-to-copper connections.

The copper pads on the surfaces of the ASIC die and the optical sensor die may be connected to metal levels of the redistribution layers of respective dies using, for example, metal-filled through-silicon vias (TSVs).

An assembly of the ASIC die bonded to the optical sensor die may be referred to herein as the SWIR-Visible light optical sensor assembly or simply the optical sensor assembly.

In some example implementations, SWIR-Visible light optical sensor assembly described herein may be configured for SWIR imaging under front side illumination (FSI) of the optical sensor assembly. The SWIR-Visible light optical sensor assembly may be referred to as being front side illuminated because incident light passes through a portion or layer of the SWIR-Visible light optical sensor assembly that, for example, includes wiring or metal levels of a redistribution layer before passing through to the silicon layer that may include the SWIR detector and the visible light detector devices such as photodiodes. In the descriptions herein, a top side of an element or structure may refer to the side of an element or structure facing the direction of incident radiation or light. A bottom side of the element or structure may refer to the side opposite the top side.

In some implementations, a bottom side of the front-side illuminated optical sensor die may be hybrid bonded to the top side of the ASIC die with electrical connections between the two dies.

In some other example implementations, the SWIR-Visible light optical sensor assembly described herein may be configured for SWIR imaging under back side illumination (BSI) of the optical sensor assembly. A back-illuminated SWIR-Visible light optical sensor assembly may contain the same elements as the front-illuminated SWIR-Visible light optical sensor assembly, however, the layer including the wiring, or the metal levels of the redistribution layer are placed behind the silicon layer so that light incident on the SWIR-Visible light optical sensor assembly illuminates the silicon layer first before passing through to the layer including the wiring or the metal levels of the redistribution layer.

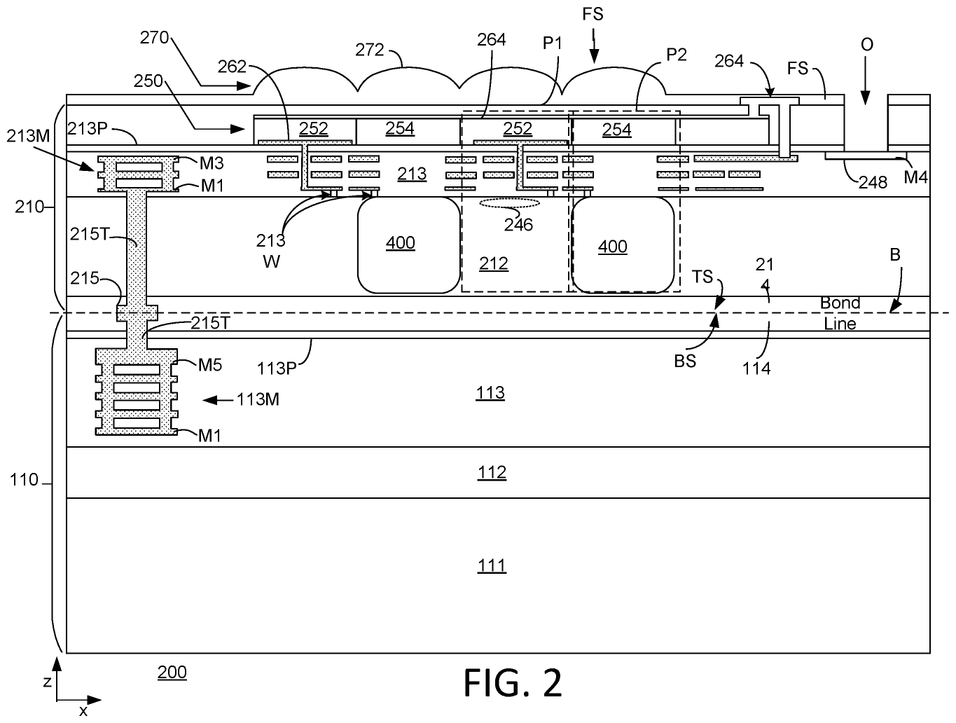

FIG. 2 shows an example SWIR-Visible light optical sensor assembly 200 configured for SWIR imaging under front side illumination (FSI). The cross-sectional view shown is taken along line A-A in FIG. 1B. A direction of frontside illumination is indicated, for example, by an arrow that is marked FSI at the top of the figure.

As shown in FIG. 2, in example implementations, SWIR-Visible light optical sensor assembly 200 includes an ASIC die 110 placed underneath and bonded to an optical sensor die 210.

ASIC die 110 may include an ASIC layer 112 fabricated on or in a semiconductor substrate 111. ASIC layer 112 may include devices and circuits such as diodes and transistors (not shown) for image signal processing. ASIC die 110 may further include an intermetal dielectric layer (IMD layer 113) and a passivation layer 113P disposed on ASIC layer 112. IMD layer 113 may include metal levels 113M for example, metal level M1 through M5, of a redistribution layer for distributing electrical signals to and from the devices and circuits in ASIC die 110.

An oxide layer 114 may be disposed on IMD layer 113. A top surface TS of oxide layer 114 may form a bonding surface for bonding ASIC die 110 to optical sensor die 210 across, for example, a bond line indicated as dashed line B in FIG. 2.

In example implementations, a metal pad may be embedded in oxide layer 114 at about top surface TS. In some implementations, the metal pad can be a copper pad 115. The top surface TS of oxide layer 114 including copper pad 115 may planarized, for example, by chemical mechanical polishing (CMP), to prepare a bonding surface for bonding optical sensor die 210 across, for example, the bond line indicated as dashed line B in FIG. 2.

Copper pad 115 may be electrically connected by a metal filled through-substrate via to the metal levels 113M, for example, metal levels M1 through M5, of the redistribution layer for distributing electrical signals to and from the devices and circuits in ASIC die 110. In some implementations, the metal filled through-substrate via can be TSV 115T. In example implementations, the metal levels M1 through M5, of the redistribution layer in ASIC die 110 may be made of a metal such as copper and aluminum, or a metal alloy.

In SWIR-Visible light optical sensor assembly 200 shown in FIG. 2, optical sensor die 210 may include an intermetal dielectric layer (IMD layer 213) disposed on a semiconductor substrate (silicon substrate 212). A color filter array (CFA 250) may be disposed on IMD layer 213. A passivation layer 213P may be disposed between, for example, CFA 250 and IMD layer 213.

CFA 250 may include, for example, a row of IR filter elements 252 alternating with green color filter elements 254. The filter elements 254 can be the filter elements along line A-A illustrated in FIG. 1B. The green color filter elements 254, which may be made of organic material, may allow green color light to pass through and interact with photodetectors such a photodiode 400 disposed in silicon substrate 212 underneath the green color filter elements 254.

In example implementations, IR filter elements 252 in CFA 250 may, for example, include an optically sensitive layer of colloidal quantum dots. The layer of colloidal quantum dots may, for example, include semiconductor nanocrystals dispersed in an organic film. The IR filter elements 252 may be disposed between a bottom electrode 262 and a top electrode 264. Bottom electrode 262 may be made, for example, tantalum or copper, and may be disposed on passivation layer 213P on top of IMD layer 213. Top electrode 264 may be formed, for example, of material such as indium tin oxide (ITO) doped with Al and ZnO that is transparent to SWIR and visible light. Bottom electrode 262, top electrode 264, and the layer of colloidal semiconductor nanocrystals of the IR filter elements 252 may form a capacitive structure that can collect charge generated in the layer of colloidal semiconductor nanocrystals by incident SWIR.

The colloidal semiconductor nanocrystals in IR filter elements 252 may include, for example, at least one of lead sulfide (PbS), indium arsenide (InAs), indium phosphide (InP), lead selenide (PbSe), cadmium sulfide (CdS), cadmium selenide (CdSe), indium gallium arsenide (InxGaₗ₋ₓAs), cadmium mercury telluride (CdHgTe), zinc selenide (ZnSe), lead oxide (PbO), and lead sulphate (PbSO₄), or combinations thereof.

CFA 250 may extend across an array of pixels P. FIG. 2 shows, for example, an example pair of pixels as rectangles marked in dashed line. The pair of pixels can include pixel P1 and pixel P2. In example implementations, the number of pixels in an imager may, for example, be in the hundreds of thousands or even in the millions.

As shown in FIG. 2, top electrode 264 disposed on the IR filter elements 252 may extend over all the pixels including those associated with color filter elements, for example, green color filter elements 254. In some implementations, all pixels P may share a common top electrode 264, while each pixel P associated with an IR filter element 252 may have an individual bottom electrode. The individual bottom electrode can include electrode 262. In example implementations, top electrode 264 and bottom electrode 262 may, for example, be made of a metal and/or an at least partially transparent material. The transparent material can include, for example, indium tin oxide, indium oxide, tungsten oxide, aluminum, gold, platinum, silver, magnesium, copper, and combinations and layer structures thereof. In example implementations, the top electrode 262 may, for example, be an indium tin oxide (ITO) material doped with ZnO and Al. In example implementations, the bottom electrode 262 may, for example, be a patterned layer of metals including, for example, one or more of copper, tantalum, titanium, or tungsten.

In optical sensor die 210, the intermetal dielectric layer (IMD layer 213) may include metal levels 213M, for example, metal level M1, M2, M3, and/or M4, of a redistribution layer for distributing electrical signals to and from pixel devices 246 in each pixel. Pixel devices 246 may be fabricated, for example, in, or on, silicon substrate 212. In example implementations, pixel devices 246 may include diodes, transistors, and/or amplifiers. The electrical signals distributed over the metal levels 213M can, for example, include the outputs of the IR filter elements 252 in pixel P1 and the outputs of photodiodes 400 in pixel P2. In example implementations, pixel devices 246 may be coupled to outputs the IR filter elements 252 that include the colloidal quantum dots. In some example implementations, bottom electrode 262 may be connected to a metal level for example, metal level M1, in metal levels 213M. In example implementations, a metal-filled via 213T passing through IMD layer 213 may connect bottom electrode 262 to a metal level M1. In example implementations, the metal levels MI through M3, of the redistribution layer in optical sensor die 210 may be made of a metal or a metal alloy. The metal or metal alloy can include, for example, copper, or aluminum. In example implementations, tungsten contacts 213W may connect metal level M1 to pixel devices 246 fabricated in, or on, silicon substrate 212.

In optical sensor die 210, silicon substrate 212 may be a thinned silicon substrate. An oxide layer 214 may be disposed on a back side of silicon substrate 212. A bottom surface BS of oxide layer 214 may form a bonding surface for bonding silicon substrate 212 to ASIC die 110 across, for example, the bond line indicated as dashed line B in FIG. 2.

In example implementations, a copper pad 215 may be embedded in oxide layer 214 at about bottom surface BS or about the bond line B. The bottom surface BS of oxide layer 214 including copper pad 215 may planarized, for example, by a chemical mechanical polishing (CMP) process, to prepare a bonding surface for bonding optical sensor die 210 to ASIC die 110 across the bond line indicated as dashed line B in FIG. 2.

Copper pad 215 embedded in oxide layer 214 may be electrically connected by a metal-filled through substrate via such as, TSV 215T, to the metal levels 213M of the redistribution layer for distributing electrical signals to and from the devices and circuits in optical sensor die 210. The metal levels 213M can include, for example, metal level M1 through M3.

In example implementations, for bonding ASIC die 110 to optical sensor die 210, surface TS of oxide layer 114 of ASIC die 110 and surface BS of oxide layer 214 of optical sensor die 210, are positioned against each other face-to-face and bonded together in a hybrid bonding process. The hybrid bonding process involves, for example, an oxide-to-oxide and a metal-to-metal bonding process.

In example implementations, copper pad 115 in oxide layer 114 and copper pad 215 in oxide layer 214 may be aligned and joined together in the hybrid bonding process. The hybrid bonding process may involve low temperature treatments of the bonded assembly, which can result in copper interdiffusion to join copper pad 115 and copper pad 215 together. The low temperature treatments may, for example, involve temperatures of about 200° C. to about 250° C. The joining of copper pad 115 and the copper pad 215 may electrically connect the redistribution layers, for example, metal level M1 through M5, and metal level M1 through M3, of the two dies for exchanging electrical signals between ASIC die 110 and optical sensor die 210.

The metal levels M1 through M3 of optical sensor die 210, and the metal levels M1 through M5 of ASIC die 110, may be made of copper. In an example implementation, the redistribution layer in optical sensor die 210, may include a further metal level M4 disposed in IMD layer 213. Metal level M4 may include an aluminum pad 248 that is accessible through an opening O at a top of optical sensor die 210, for example, for wire bonding external wire connections to the die.

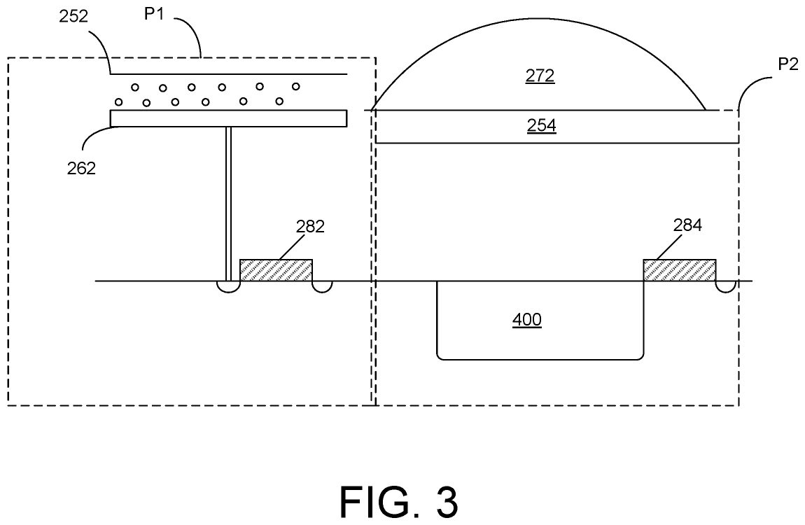

In example implementation, optical sensor die 210 may include a microlens array, for example, array 270 of microlens 272, disposed on a front surface FS of the die to help funnel incoming light into each pixel P. In example implementations, as shown in FIG. 3, microlens 272 may be placed only above the color filter elements, for example, the red, blue, and green color filter elements, in CFA 250. Microlens 272 may not be placed above the IR filter elements in CFA 250. FIG. 3 shows, for example, microlens 272 placed only above the color filter elements such as green color filter elements 254, but not above IR filter element 252 in CFA 250.

FIG. 3 also shows bottom electrode 262 of IR filter element 252 connected to a transistor 282, and photodiode 400 associated, for example, with a color pixel connected to a transistor 284. Transistor 282 and transistor 284 may be part of a device 246 formed in or on silicon substate 212. In example implementations, devices 246 may be used to read or clear charges accumulated or induced in the respective pixels by SWIR or visible light.

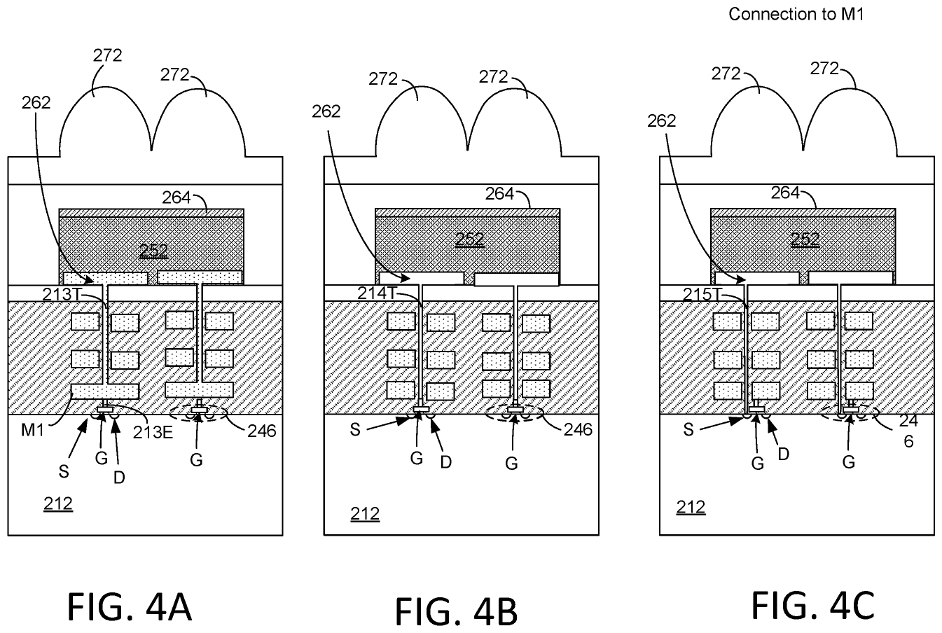

In example implementations, each pixel P may be associated with a pixel device 246 that may be fabricated in or on silicon substrate 212. In example implementations, device 246 may be a MOSFET device or other transistor fabricated in, or on a surface, of silicon substrate 212. As shown in FIG. 4A through FIG. 4C, device 246 may include a polysilicon gate G disposed on the surface of silicon substrate 212 and heavily doped source and drain regions disposed in, or on, the surface of substrate 212. The source region can include source S and the drain region can include drain D.

In some example implementations, as shown in FIG. 4A, the bottom electrode 262 disposed underneath IR filter element 252 in a pixel P1 may be connected to metal level Ml by a metal-filled via 213T, and further connected to a polysilicon gate G disposed on the surface of silicon substrate 212 by a metal-filled via extension 213E of the metal-filled via 213T.

In some example implementations, as shown in FIG. 4B, the electrode 262 disposed underneath IR filter element 252 may be connected to only the polysilicon gate G disposed on the surface of silicon substrate 212 by a metal-filled via 214T.

In some example implementations, as shown in FIG. 4C, bottom electrode 262 disposed underneath an IR filter element 252 may be connected to only the heavily doped source S disposed in or on the surface of substrate 212 by a metal-filled via 215T.

In example implementations, metal-filled via 213T, 214T and 215T may, for example, be Ti/W filled vias. Electrode 262 may be composed, for example, of titanium and tungsten.

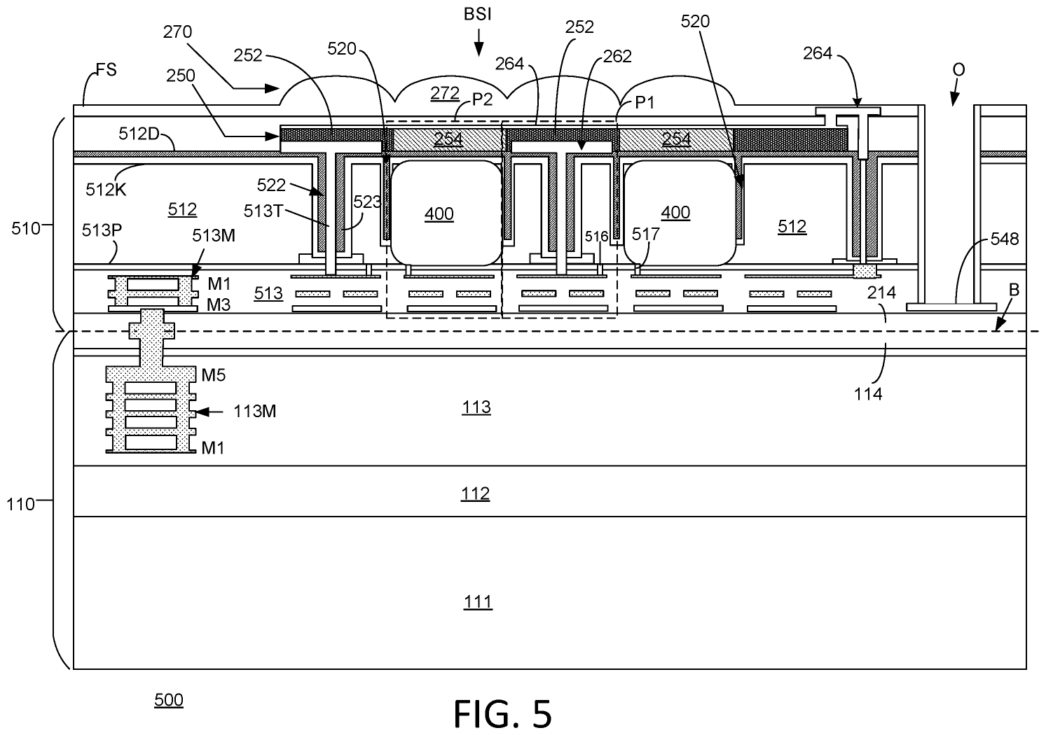

FIG. 5 shows an example SWIR-Visible light optical sensor assembly 500 configured for SWIR imaging under backside illumination (BSI). The cross-sectional view shown in FIG. 5 is taken along line A-A in FIG. 1B. A direction of backside illumination is indicated, for example, by an arrow that is marked BSI at the top of the figure.

As shown in FIG. 5, in example implementations, SWIR-Visible light optical sensor assembly 500 includes an optical sensor die 510 that includes color filter array, for example, CFA 250, disposed on a top surface of a thinned silicon substrate 512. An IMD layer 513 may be disposed underneath silicon substrate 512. A passivation layer 513P may be disposed between silicon substrate 512 and IMD layer 513. An ASIC die 110 is placed underneath and bonded to the optical sensor die 510 using, for example, a hybrid bonding process. The hybrid bonding process may be the same or similar to the hybrid bonding process described above in the context of SWIR-Visible light optical sensor assembly 200.

In the SWIR-Visible light optical sensor assembly 500 shown in FIG. 5, a pattern of SWIR detector pixels and visible light detecting pixels may be formed in silicon substrate 512. FIG. 5 shows, for example, a SWIR pixel P1 and a visible light detector pixel P2 formed in silicon substrate 512. CFA 250 disposed on the top surface of silicon substrate 512 may include, for example, a row of IR filter elements 252 alternating with green color filter elements 254 similar to the filter elements IR-G-IR-G along line A-A shown in FIG. 1B. The IR filter elements 252 may be aligned with the SWIR pixels, for example, pixel P1, and the green color filter elements 254 may be aligned with visible color pixels, for example, pixel P2. The green color filter elements 254, which may be made of organic material, may allow green color light to pass through and interact with photodetectors such photodiodes 400 formed in silicon substrate 512 underneath the green color filter elements 254.

CFA 250 may extend across an array of pixels of assorted color types and patterns. FIG. 5 shows, for example, a pair of adjacent pixels: a SWIR pixel P1 and a visible light detector pixel P2, as adjacent rectangles marked in dashed line. In example implementations, the number of pixels in an imager may, for example, be in the hundreds of thousands or even in the millions.

Silicon substrate 512 as used in SWIR-Visible light optical sensor assembly 500 may be referred to herein as backside illuminated silicon (BSI silicon).

In example implementations, IR filter elements 252 in CFA 250 may, for example, include an optically sensitive layer of colloidal quantum dots. The layer of colloidal quantum dots, may, for example, include semiconductor nanocrystals dispersed in an organic film. The IR filter elements 252 may be disposed between a bottom electrode 262 and a top electrode 264. Bottom electrode 262 may be made, for example, tantalum or copper, and may be disposed on a passivation layer disposed on silicon substrate 512. Top electrode 264 may be formed, for example, of material such as doped indium tin oxide (ITO) that is transparent to SWIR and visible light. Bottom electrode 262, top electrode 264, and the layer of colloidal semiconductor nanocrystals of the IR filter elements 252 may form a capacitive structure that can collect charge generated or induced in the layer of colloidal semiconductor nanocrystals by incident SWIR.

In some example implementations, as shown in FIG. 5, top electrode 264 made, for example, of ITO, may extend over both SWIR and visible light pixels. In some other example implementation, top electrode 264 made, for example, of ITO, may extend only over the SWIR pixels (P1).

In example implementations, deep isolation trenches, for example, trenches 520, may be formed to isolate photodiodes 400 formed in silicon substrate 512 in the color pixels, for example, pixel P2, from the BSI silicon in the SWIR pixels, for example, pixel P1. While the deep isolation trenches 520 are shown in FIG. 5 as extending only partially through the depth of silicon substrate 512, they may extend all the way through the silicon substrate 512. Also, in example implementations, the deep isolation trenches may be formed from the frontside or the same side as IMD layer 513, in which case they may be filled with polysilicon and SiO2 or W metal or any other combination.

Further, a through silicon via, for example, TSV 522, may be formed in each SWIR pixel P1, extending from a top surface of silicon substrate 512 to a metal level, for example, metal level M1 in IMD layer 513 disposed underneath silicon substrate 512.

In example implementations, the top surface of silicon substrate 512 (and other exposed surfaces including, for example, sidewalls of trenches 520 and TSV 522, may be coated with passivating dielectrics including, for example, a high-k dielectric layer 512K, and an oxide layer 512D, or other dielectrics. High-k dielectric layer 512K may, for example, be include high-k dielectrics, such as Al2O3/HfO2/Ta2O5.

In example implementations, TSV 522 may be lined with oxide 523 and filled with a metal plug 513T to electrically connect bottom electrode 262 in the SWIR pixels (P1) to metal level M1. Metal plug 513T may, for example, include tungsten, tantalum, or copper.

IR filter elements 252 may, for example, include colloidal semiconductor nanocrystals dispersed in a film that may, for example, be spun on as an organic fluid colloid on silicon substrate 512. The semiconductor nanocrystals (quantum dot photodetectors) may include, for example, at least one of PbS, InAs, InP, PbSe, CdS, CdSe, InxGaₗ₋ₓAs, (Cd—Hg) Te, ZnSe (PbS), ZnS (CdSe), ZnSe (CdS), PbO (PbS), and PbSO4(PbS) nanocrystals or other semiconductor quantum dots.

As shown in FIG. 5, pixel P1 includes a top electrode 264 disposed on CFA 250 and a bottom electrode 262 disposed underneath IR filter element 252 in each pixel P1. All pixels P1 may share a common top electrode 264 while each pixel P1 may have an individual bottom electrode 262. In example implementations, top electrode 264 and bottom electrode 262 may, for example, be made of a metal and/or an at least partially transparent material. Top electrode 264 may, for example, include indium tin oxide, indium oxide, tungsten oxide, aluminum, gold, platinum, silver, magnesium, or copper, and combinations and layer structures thereof. In an example implementation, the top electrode may, for example, be an indium tin oxide (ITO) material doped with ZnO and Al. In example implementations, bottom electrode 262 may, for example, be a patterned layer of metal including, for example, one or more of copper, tantalum, titanium, or tungsten.

In example implementations, top electrode 264 and the bottom electrode 262 in each pixel PI may be connected to a metal level, for example, metal level M1, in IMD layer 513 disposed underneath silicon substrate 512. The connection may be made, for example, by metal plug 513T disposed in TSV 522. TSV 522 may be filled or lined with oxide layer 512D and/or oxide 523 for passivation.

In example implementations, each pixel contact may be made with tantalum, titanium nitride and tungsten (Ta/TiN/W) contacts including, for example, bottom electrode 262. Each pixel contact may be isolated, creating a high value capacitor with the high-k dielectric layer 512K that, for example, lines the top surface of the silicon substrate 512 and the sidewalls of TSV 522. The high-k dielectric layer may, for example, include aluminum oxide, hafnium oxide, and tantalum oxide (Al2O3/HfO2/Ta2O5). The high value capacitor may store charge generated in IR filter element 252 by incident SWIR, for example, for periodic readout.

In optical sensor die 510, IMD layer 513 may include metal levels 513M of a redistribution layer for distributing electrical signals in each pixel P1 and P2 to and from pixel devices that may be fabricated in or on silicon substrate 512. The metal levels 513M may, for example, include metal level M1 through metal level M3. The fabricated devices (not shown) may include, for example, diodes, transistors, or amplifiers. In some example implementations, tungsten-filled plugs 516, 517 extending from metal level MI into the silicon substrate can establish electrical connection to a pixel device, for example, a transistor, fabricated in or on silicon substrate 512. For example, a tungsten-filled plug 516 and a tungsten-filled plug 517 extending from metal level M1 into pixel P2 and pixel P1, respectively, can establish electrical connection to respective pixel devices (for example, a transistor) formed in the silicon substrate,

In some example implementations, the redistribution layer in optical sensor die 510 may include an aluminum pad 548 that is accessible through an opening O at a top of optical sensor die 510, for example, for wire bonding external wire connections to the die.

In example implementation, optical sensor die 510 may include a microlens array, for example, array 270 disposed on a front surface FS of the die to help funnel incoming light into each pixel P. In example implementations, microlens 272 may be placed only above the color filter elements, for example, the red, green, and blue color filter elements, in CFA 250. In some example implementations, Microlens 272 may not be placed above the IR filter elements 252 in CFA 250.

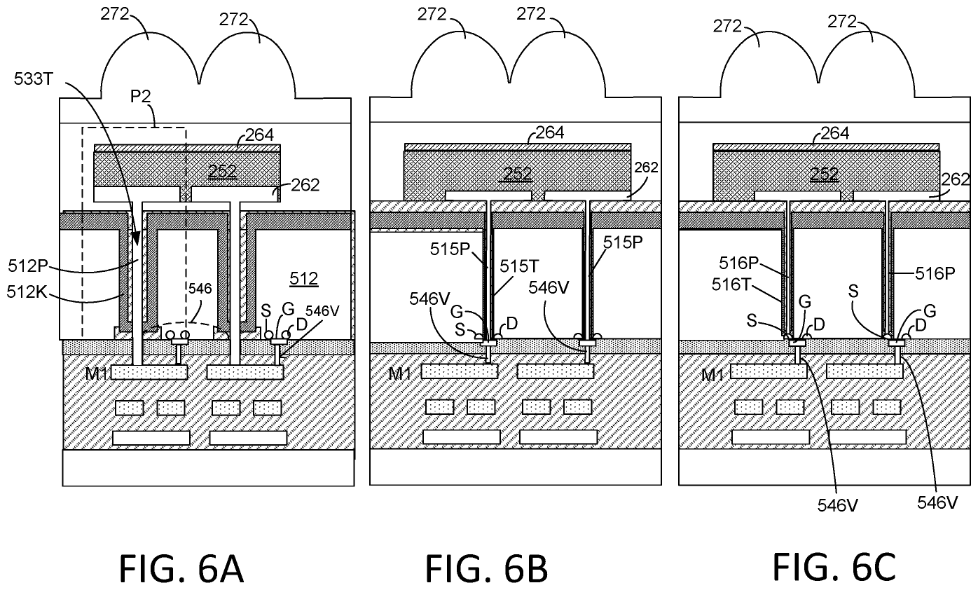

In some example implementations, as shown in FIG. 6A, the bottom electrode 262 disposed underneath SWIR filter element 252 may be first connected to the metal level M1 by a metal plug 512P disposed in a through-silicon via 513T extending through silicon substrate 512. Further, metal level M1 may be independently connected to the polysilicon gate G of a pixel device 546 by a metal-filled via 546V passing through IMD layer 513.

In some example implementations, as shown in FIG. 6B, the bottom electrode 262 disposed underneath SWIR filter element 252 may be directly connected to the polysilicon gate G of a pixel device by a metal plug 515P disposed in a through-silicon via 515T extending through silicon substrate 512 and terminating at the polysilicon gate G of the pixel device.

In some example implementations, as shown in FIG. 6C, the bottom electrode 262 disposed underneath SWIR filter element 252 may be connected directly to a heavily doped source S of pixel device 546 by metal plug 516P. Metal plug 516P may be disposed in a through-silicon via 516T extending through silicon substrate 512. Further, metal level M1 also may be independently connected to the polysilicon gate G of the pixel device by a metal-filled via 546V extending from the M1 layer through IMD layer 513 to the polysilicon gate G.

In some example implementations, optical sensor die 210 and optical sensor die 510 described in the foregoing may include infrared sensitivity enhancement features, to improve visual images. An example enhancement feature may include a diffractive inverted pyramid array (IPA) structure disposed on the silicon substrate in the visible color pixels. The IPA structure may be light trapping and may increase the absorption of light incident on the visual color pixels. In example implementations, the IPA structure may be disposed on top of the photodetector in the pixel to detect near infrared light.

In example implementations, the IPA structures can increase the IR sensitivity of the visual images. Further, the IPA structure in conjunction with the deep trench isolation of the pixels, can reduce effects of cross-talk between pixels.

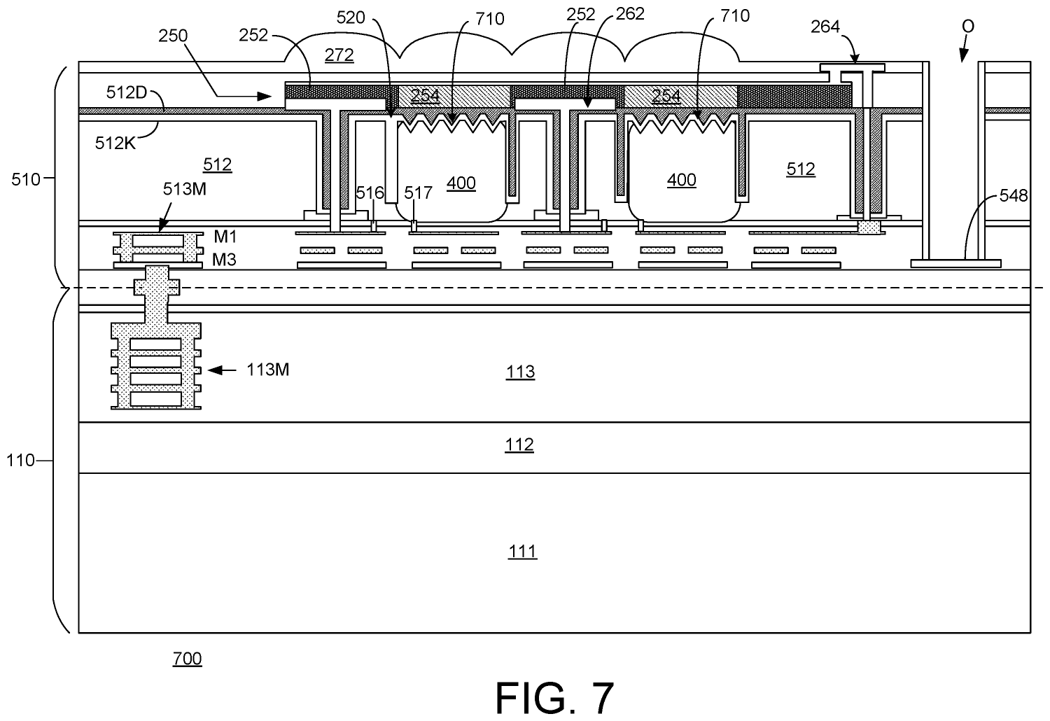

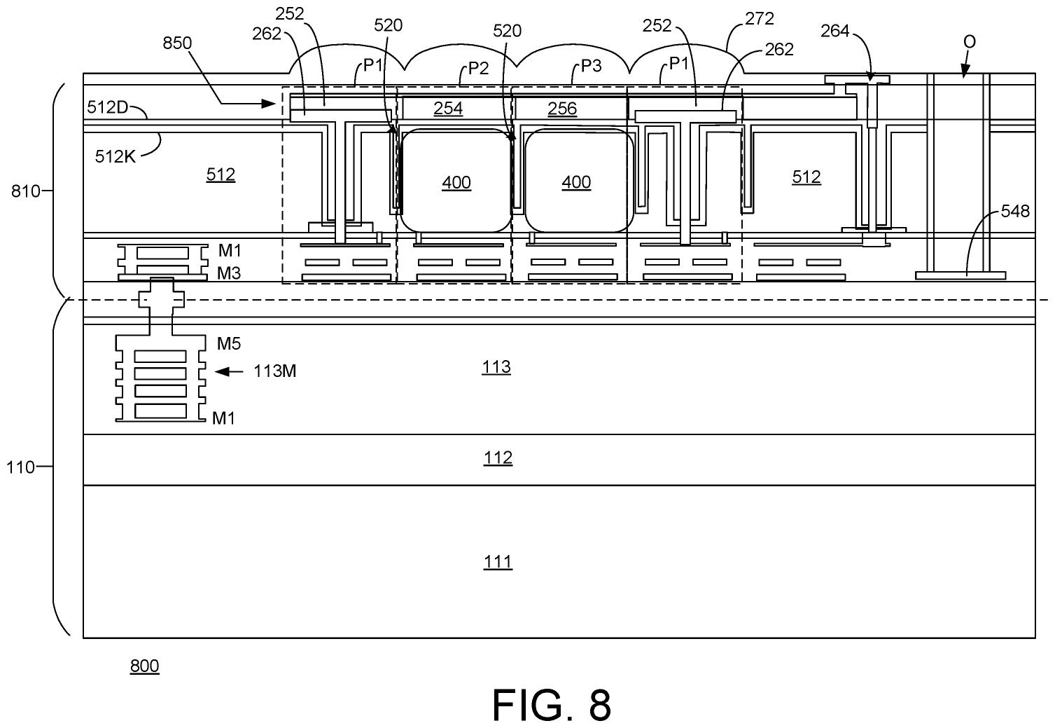

FIG. 7 shows an example SWIR-Visible light optical sensor assembly 700. SWIR-Visible light optical sensor assembly 700 may generally have the same structure and characteristics as SWIR-Visible light optical sensor assembly 500 shown in FIG. 5. However, the SWIR-Visible light optical sensor assembly 700 shown in FIG. 7 further includes infrared sensitivity enhancement features. For example, as shown in FIG. 7, an inverted pyramid structure 710 may be formed on the top surfaces of photodiodes 400 disposed in silicon substrate 512 underneath the color filter elements, for example, the green color filter elements 254. Inverted pyramid structure 710 may diffractively trap light and increase absorption of light incident on photodiodes 400 to enhance the IR sensitivity of the sensor.

FIG. 8 shows a cross-sectional view of an example combined SWIR-Visible light optical sensor assembly 800 configured for SWIR imaging under back side illumination (BSI). The cross-sectional view shown is taken along line C-C in FIG. 1C. A direction of back side illumination is indicated, for example, by an arrow that is marked BSI at the top of the figure.

SWIR-Visible light optical sensor assembly 800 includes an ASIC die 110 placed underneath and bonded to an optical sensor die 810. Optical sensor die 810 may include a pixel arrangement in which an IR filter element is located at a center of a 2-×2 RGGB pattern of color filter elements, as shown for example in FIG. 1C.

In combined SWIR-Visible light optical sensor assembly 800, a CFA 850 is disposed on the top surface of silicon substrate 512. CFA 850 may include, for example, a row of IR filter elements 252 with each IR filter element placed at the center of a 2-by-2 pattern of color filter elements B-G-G-R. The IR filter elements 252 may be aligned with the SWIR pixels, for example, pixel P1. The green color filter elements 254 may be aligned with visible light pixels, for example, pixel P2. The red color filter elements 256 may be aligned with visible light pixels, for example, pixel P3. Blue color filter elements in the B-G-G-R pattern may be associated with corresponding blue color visible light pixels, but the blue color pixels are not visible in the cross-sectional view shown in FIG. 8. Green and red color filter elements 254 and 256, which may be made of organic material, may respectively allow green color light and red color light to pass through and interact with photodiodes 400 disposed in silicon substrate 512 underneath the green color filter elements 254 and red color filter elements 256.

In example implementations, IR filter elements 252 in CFA 850 may be surrounded by the backside deep isolation trenches (for example, trenches 520) extending at least partially through a thickness of silicon substrate 512. The deep trench isolation trenches extending through silicon substrate 512 may also separate the visible light pixels P2 and P3. While the deep trenches are shown as extending partially inside the silicon, in example implementations, the deep trenches may extend all the way through silicon substrate 512. Also, the deep trenches may be formed from the frontside, in which case they may be filled with polysilicon and SiO2 or W metal or any other combination of materials.

The deep trench isolation trenches 520 may consume silicon that would otherwise be part of the adjoining pixels.

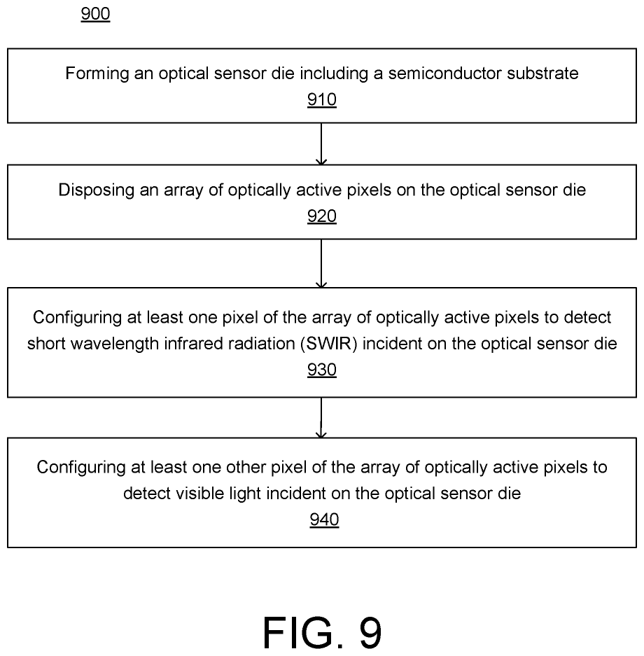

FIG. 9 shows an example method 900 for combining SWIR detection and visible light detection in a single optical sensor.

Method 900 includes forming an optical sensor die including a semiconductor substrate (910). At least one device is fabricated in the semiconductor substrate.

Method 900 further includes disposing an array of optically active pixels on the optical sensor die (920), configuring at least one pixel of the array of optically active pixels to detect short wavelength infrared radiation (SWIR) incident on the optical sensor die (930), and configuring at least one other pixel of the array of optically active pixels to detect visible light incident on the optical sensor die (940).

In example implementations of method 900 configuring at least one pixel of the array of optically active pixels to detect SWIR 930 includes disposing a layer of quantum colloidal dots between a top electrode and a bottom electrode in the pixel.

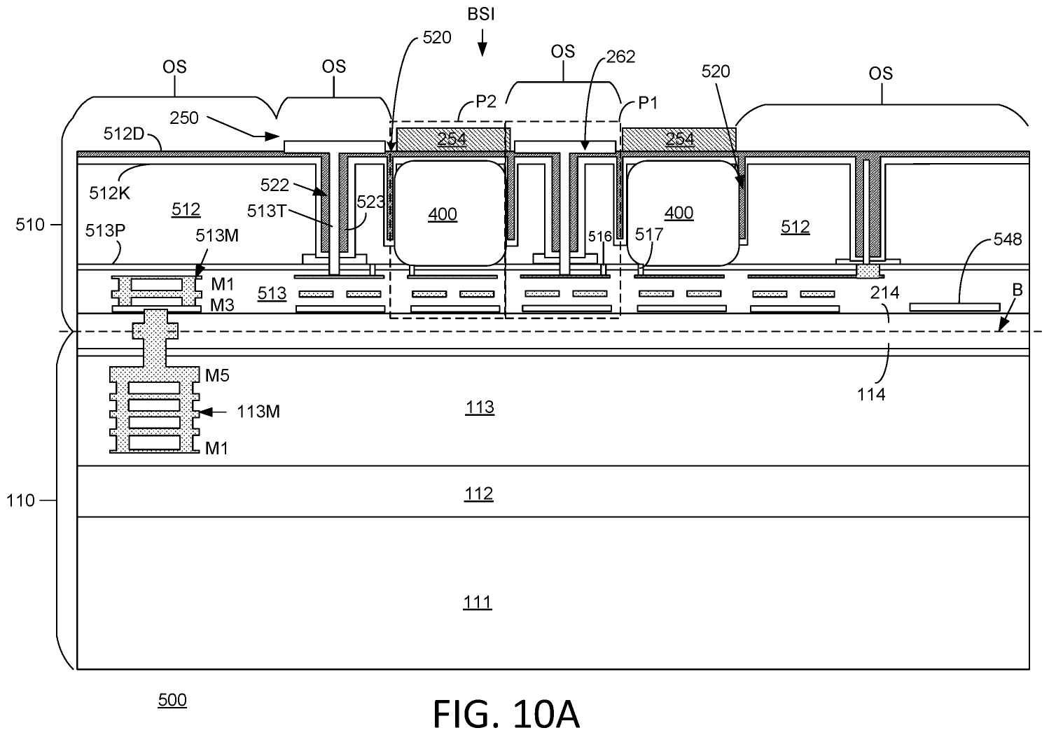

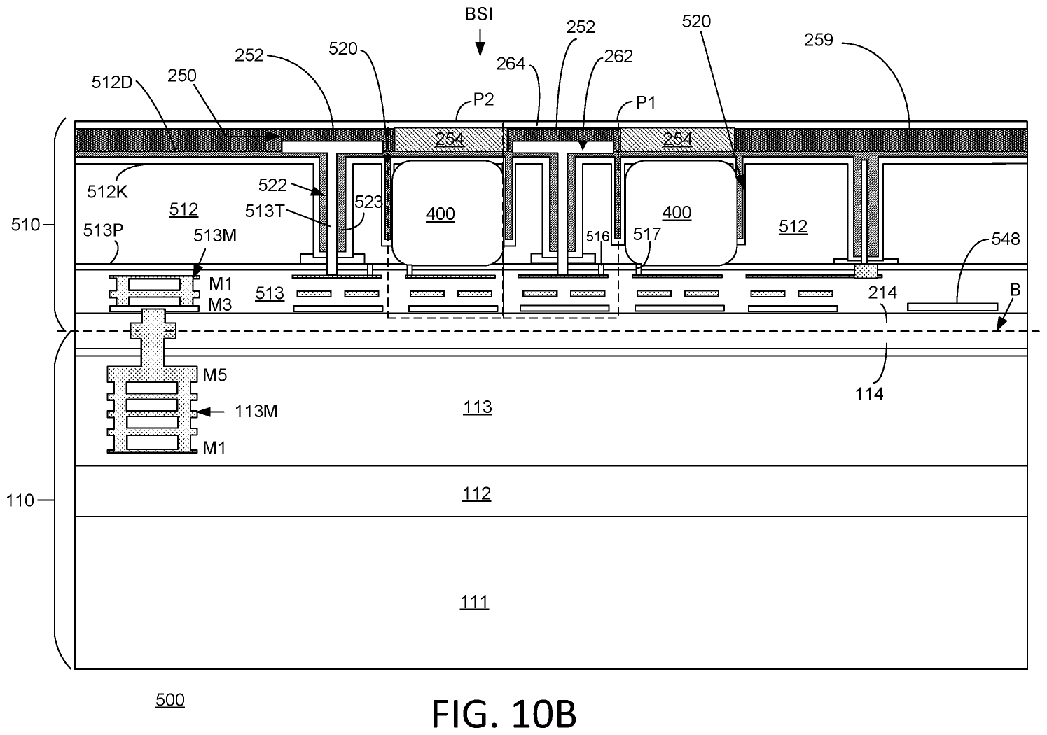

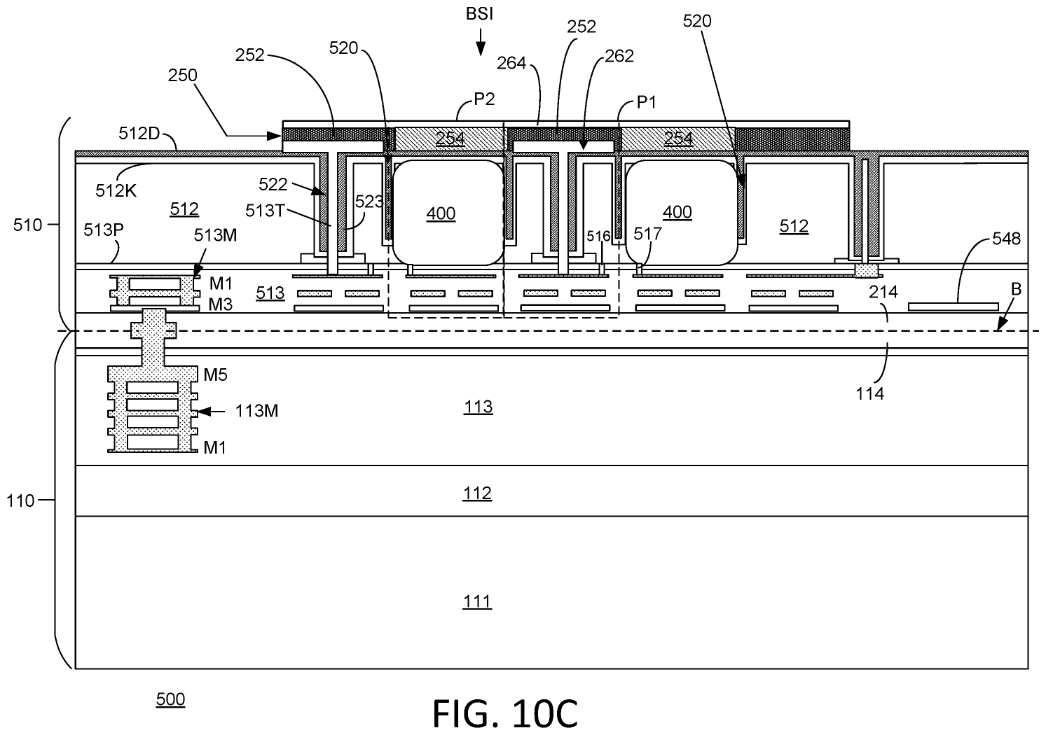

In example implementations of method 900, configuring at least one pixel of the array of optically active pixels to detect visible light 940 includes forming a photodiode in the pixel. In example implementations, method 900 further includes disposing a diffractive inverted pyramid structure on the photodiode formed in the semiconductor die to detect near infrared light. Example implementations related to steps 930 and 940 are described below in connection with FIGS. 10A through 10C.

In example implementations, as described below with reference to FIG. 10A through FIG. 10C, steps 930 and 940 of method 900 may involve disposing a layer of color photoresists including a pattern of color filter elements, for example, the green color filter elements 254, above the array of optically active pixels, for example, pixels P1 and P2. The layer of the color photoresists may be then patterned to define openings, for example, openings OS, for at least one SWIR filter element, for example, SWIR filter element 252. A layer of colloidal quantum dot material may then be applied above the layer of colored filter elements to fill the openings for the at least one SWIR filter element 252. Excess colloidal quantum dot material above the color filter elements may be etched away by a photolithography process or removed by chemical mechanical polishing (CMP). A layer of ITO may then be applied above the layer of colored filter elements and the layer of colloidal quantum dot material. The layer of ITO may form top electrode 264 for the SWIR filter element 252.

FIGS. 10A through 10C also illustrate, for example, the formation of the mosaic of color filter elements and SWIR filter elements. FIG. 10A shows, for example, a stage of construction at which a layer of color photo resists, for example, layer 250, including, for example, the green color filter elements 254, is disposed above the array of optically active pixels, for example, pixels P1 and P2. Openings OS may be made in layer 250 to receive, at the next stage of construction, colloidal quantum dot material for the least one SWIR filter element 252.

FIG. 10B shows a layer of quantum colloidal dots 254 and a layer of ITO 264 applied above the structure to fill openings OS and form the IR filter elements, for example, IR filter elements, 252. Excess quantum colloidal dots material 259 and ITO material 269 may extend outside the area of the array of optically active pixels.

FIG. 10C shows the excess quantum colloidal dots material and ITO material 269 that may, for example extend over the areas outside the array of optically active pixels may be removed by etching.

In some example implementations, a layer of colloidal quantum dot material may be first disposed above all the optically active pixels. The layer of colloidal material may then be covered with a protective layer (e.g., SiO2 or Si3N4) and may then be patterned and etched to form openings to receive colored resists for the plurality of visible light color filter elements.

In example implementations, the mosaic has filter elements arranged in at least one of:
A) An RGB-IR 2×2 format including 1 Red, 1 Blue, 1 Green, and 1 SWIR filter element for a total of four filter elements;
B) An RGB-IR 4×4 format including 2 Red, 2 Blue, 8 Green, and 4 SWIR filter element for a total of sixteen filter element; or
C) An RGB 2×2+IR format including 1 Red, 1 Blue, 2 Green, and 1SWIR filter element at a center of a 2×2 RGB square for a total of five filter elements, the SWIR filter element being less than one pixel in size.

In example implementations, method 900 further includes disposing a diffractive inverted pyramid structure on the photodiode formed in the semiconductor die to detect near infrared light.

In example implementations, method 900 further includes disposing an array of microlenses at least over the plurality of visible light color filter elements.

In example implementations, method 900 further includes bonding and electrically connecting an application-specific integrated circuit (ASIC) die to the semiconductor die.

While certain features of the described implementations have been illustrated as described herein, many modifications, substitutions, changes, and equivalents will now occur to those skilled in the art. It is, therefore, to be understood that the appended claims are intended to cover all such modifications and changes as fall within the scope of the implementations. It should be understood that they have been presented by way of example only, not limitation, and various changes in form and details may be made. Any portion of the apparatus and/or methods described herein may be combined in any combination, except mutually exclusive combinations. The implementations described herein can include various combinations and/or sub-combinations of the functions, components and/or features of the different implementations described.

It will be understood that, in the foregoing description, when an element is referred to as being on, connected to, electrically connected to, coupled to, or electrically coupled to another element, it may be directly on, connected or coupled to the other element, or one or more intervening elements may be present. In contrast, when an element is referred to as being directly on, directly connected to or directly coupled to another element, there are no intervening elements present. Although the terms directly on, directly connected to, or directly coupled to may not be used throughout the detailed description, elements that are shown as being directly on, directly connected or directly coupled can be referred to as such. The claims of the application, if any, may be amended to recite exemplary relationships described in the specification or shown in the figures.

As used in this specification, a singular form may, unless definitely indicating a particular case in terms of the context, include a plural form. Spatially relative terms such as over, above, upper, under, beneath, below, lower, and so forth, are intended to encompass different orientations of the device in use or operation in addition to the orientation depicted in the figures. In some implementations, the relative terms above and below can, respectively, include vertically above and vertically below. In some implementations, the term adjacent can include laterally adjacent to or horizontally adjacent to.

Unless defined otherwise, all technical and scientific terms used herein have the same meaning as commonly understood by one of ordinary skill in the art. Methods and materials similar or equivalent to those described herein can be used in the practice or testing of the present disclosure. As used in the specification, and in the appended claims, the singular forms “a,” “an,” “the” include plural referents unless the context clearly dictates otherwise. The term “comprising,” and variations thereof as used herein is used synonymously with the term “including” and variations thereof and are open, non-limiting terms. The terms “optional” or “optionally” used herein mean that the subsequently described feature, event or circumstance may or may not occur, and that the description includes instances where said feature, event or circumstance occurs and instances where it does not. Ranges may be expressed herein as from “about” one particular value, and/or to “about” another particular value. When such a range is expressed, an aspect includes from the one particular value and/or to the other particular value. Similarly, when values are expressed as approximations, by use of the antecedent “about,” it will be understood that the particular value forms another aspect. It will be further understood that the endpoints of each of the ranges are significant both in relation to the other endpoint, and independently of the other endpoint.

Some implementations may be implemented using various semiconductor processing and/or packaging techniques. Some implementations may be implemented using various types of semiconductor processing techniques associated with semiconductor substrates including, but not limited to, for example, Silicon (Si), Gallium Arsenide (GaAs), Gallium Nitride (GaN), Silicon Carbide (SiC) and/or so forth.

1. A sensor comprising:
an array of optically active pixels disposed on a semiconductor die, the array of optically active pixels including:
at least one pixel configured to detect short wavelength infrared radiation (SWIR), and
at least one pixel configured to detect visible light.

2. The sensor of claim 1, wherein the at least one pixel configured to detect SWIR includes a layer of quantum colloidal dots disposed between a top electrode and a bottom electrode.

3. The sensor of claim 1, wherein the at least one pixel configured to detect visible light includes a photodiode formed in the semiconductor die.

4. The sensor of claim 3, further comprising, a diffractive inverted pyramid structure disposed on the photodiode formed in the semiconductor die to detect near infrared light.

5. The sensor of claim 1, further comprising:
a color filter array disposed above the array of optically active pixels, the color filter array including a mosaic of a plurality of visible light color filter elements and at least one SWIR filter element, the least one SWIR filter element including a layer of quantum colloidal dots disposed between a top electrode and a bottom electrode.

6. The sensor of claim 5, wherein the mosaic has 1 SWIR filter element in any given 2×2 section.

7. The sensor of claim 5, wherein the mosaic has filter elements arranged in an RGB 2×2+IR format including 1 Red, 1 Blue, 2 Green, and 1 SWIR filter element at a center of a 2×2 RGB square for a total of five filter elements, the SWIR filter element being less than one pixel in size.

8. The sensor of claim 1, further comprising:
an array of microlenses disposed above the at least one pixel configured to detect visible light.

9. An imager comprising:
an optical sensor die including a semiconductor substrate, at least one device fabricated in the semiconductor substrate;
an array of optically active pixels disposed on the optical sensor die, the array of optically active pixels including at least one short wavelength infrared radiation (SWIR) pixel and at least one visible light pixel; and
an intermetal dielectric (IMD) layer disposed on a bottom surface of the semiconductor substrate, the IMD layer including at least a metal level of a redistribution layer of the optical sensor die.

10. The imager of claim 9, wherein the at least one SWIR pixel includes a layer of quantum colloidal dots disposed between a top electrode and a bottom electrode, the at least one visible light pixel includes a photodiode formed in the semiconductor substrate.

11. The imager of claim 10, wherein the layer of quantum colloidal dots includes colloidal semiconductor nanocrystals made of at least one of PbS, InAs, InP, PbSe, CdS, CdSe, InxGa1-xAs, CdHgTe, ZnSe (PbS), ZnS (CdSe), ZnSe (CdS), PbO (PbS), and PbSO₄ (PbS).

12. The imager of claim 10, further comprising, a diffractive inverted pyramid structure disposed on the photodiode formed in the semiconductor substrate to detect near infrared light.

13. The imager of claim 9, wherein a deep isolation trench etched in the semiconductor substrate isolates at least a first pixel from a second pixel in the array of optically active pixels.

14. The imager of claim 9, further comprising:
a color filter array (CFA) disposed above the array of optically active pixels, the CFA including a mosaic of a plurality of visible light color filter elements and at least one SWIR filter element, the least one SWIR filter element including a layer of quantum colloidal dots (QCD) disposed between a top electrode and a bottom electrode.

15. The imager of claim 14, further comprising:
a layer of passivating material disposed on a top surface of the semiconductor substrate underneath the CFA, the layer of passivating material including at least one of silicon dioxide and a high-k dielectric material.

16. The imager of claim 15, wherein the top electrode above the layer of QCD and the semiconductor substrate form a capacitor with the high-k dielectric material in between as a capacitive material.

17. The imager of claim 14, wherein the bottom electrode is electrically connected to a metal level in the IMD layer by a metal-filled via extending through the semiconductor substrate.

18. The imager of claim 14, wherein the bottom electrode is electrically connected by a metal-filled via extending through the semiconductor substrate to a transistor formed in or on the semiconductor substrate.

19. The imager of claim 9, wherein the semiconductor substrate is a first semiconductor substrate, the redistribution layer is a first redistribution layer, and the IMD layer is a first IMD layer, the imager further comprising:
an application specific integrated circuit (ASIC) die including a second semiconductor substrate; and
a second IMD layer disposed on the second semiconductor substrate, the second IMD layer including at least a metal level of a second redistribution layer (RDL) of the ASIC die, wherein the optical sensor die is stacked above the ASIC die with a dielectric layer disposed between the bottom surface of first semiconductor substrate and a top surface of the second IMD layer, the dielectric layer bonding the optical sensor die to the ASIC die.

20. The imager of claim 19, wherein the dielectric layer disposed between the bottom surface of first semiconductor substrate and the top surface of the second IMD layer includes a pair of copper pads that are fused together to electrically connect the first RDL of the optical sensor die and the second RDL of the ASIC die.

21. A method, comprising:
forming an optical sensor die including a semiconductor substrate, at least one device being fabricated in the semiconductor substrate;
disposing an array of optically active pixels on the optical sensor die;
configuring at least one pixel of the array of optically active pixels to detect short wavelength infrared radiation (SWIR) incident on the optical sensor die; and
configuring at least one other pixel of the array of optically active pixels to detect visible light incident on the optical sensor die.

22. The method of claim 21, wherein configuring at least one pixel of the array of optically active pixels to detect SWIR includes disposing a layer of quantum colloidal dots between a top electrode and a bottom electrode in the at least one pixel.

23. The method of claim 21, wherein configuring at least one pixel of the array of optically active pixels to detect visible light includes forming a photodiode in the at least one pixel.

24. The method of claim 23, further comprising:
disposing a diffractive inverted pyramid structure on the photodiode formed in the at least one pixel to detect near infrared light.
